(19) United States
(12) Patent Application Publication
(10) Pub. No.: US 2024/0421011 A1
(43) Pub. Date: Dec. 19, 2024

(54) SEMICONDUCTOR PACKAGE

(71) Applicant: Samsung Electronics Co., Ltd., Suwon-si (KR)

(72) Inventors: WanSun Kim, Suwon-si (KR); HYUNGGIL BAEK, Suwon-si (KR); Hojin Seo, Suwon-si (KR)

(21) Appl. No.: 18/435,689

(22) Filed: Feb. 7, 2024

(30) Foreign Application Priority Data
Jun. 13, 2023 (KR) 10-2023-0075708

(51) Int. Cl. H01L 23/18; H01L 23/00; H01L 23/498; H01L 25/065; H01L 25/18

(52) U.S. Cl. CPC H01L 23/18; H01L 23/49838; H01L 24/16; H01L 25/0655; H01L 25/0657; H01L 25/18; H01L 2224/06517; H01L 2224/16145; H01L 2224/16225; H01L 2225/06513; H01L 2924/1431; H01L 2924/1436; H01L 2924/1437; H01L 2924/1438; H01L 2924/1441; H01L 2924/14511

(57) ABSTRACT

A semiconductor package includes a package substrate, a semiconductor chip that is bonded to the package substrate, and a stiffener that is adjacent to the semiconductor chip and is bonded to the package substrate. The stiffener includes a plurality of corner parts that are bonded to a plurality of corner regions of the package substrate, and a plurality of leg parts that are spaced apart from the package substrate. Each of the plurality of leg parts connects corresponding two leg parts of the plurality of leg parts with each other.

### CROSS-REFERENCE TO RELATED APPLICATION(S)

This application claims priority under 35 U.S.C. § 119 to Korean Patent Application No. 10-2023-0075708 filed on Jun. 13, 2023 in the Korean Intellectual Property Office, the disclosure of which is incorporated by reference herein in its entirety.

### BACKGROUND OF THE INVENTION

### (a) Field of the Invention

The present disclosure relates to a semiconductor package, and more particularly, to a semiconductor package including a stiffener.

### (b) Description of the Related Art

With the advancement and diversification of semiconductor application products, semiconductor packages tend to increase in size and decrease in thickness. Accordingly, there is a problem that warpage of semiconductor packages is significantly increasing.

During a packaging process of semiconductor products, excessive warpage of a unit package may cause assembly defects such as a short circuit. Demands for controlling warpage of semiconductor packages are increasing.

In order to cope with warpage of semiconductor packages as mentioned above, products including thick structures with high moduli of elasticity applied as stiffeners for improving flexural rigidity have been being introduced; however, there is a problem that the effect of reducing warpage of, particularly, large semiconductor packages (Large PKG) is small and performance improvement is desirable.

### SUMMARY OF THE INVENTION

The present disclosure attempts to provide a semiconductor package with improved performance by improving the effect of reducing warpage of semiconductor packages of various sizes.

According to an embodiment of the present disclosure, a semiconductor package includes a package substrate, a semiconductor chip that is bonded to the package substrate, and a stiffener that is adjacent to the semiconductor chip and is bonded to the package substrate. The stiffener includes a plurality of corner parts that are bonded to a plurality of corner regions of the package substrate, and a plurality of leg parts that are spaced apart from the package substrate. Each of the plurality of leg parts connects corresponding two leg parts of the plurality of leg parts with each other.

According to an aspect of the present disclosure, a semiconductor package includes a package substrate, an interposer that is mounted on the package substrate, a semiconductor stack structure that is disposed on the interposer and in which a plurality of memory chips is vertically stacked on the interposer, a semiconductor chip that is horizontally adjacent to the semiconductor stack structure and that is mounted on the interposer, and a stiffener that is disposed on the package substrate, and that surrounds the interposer. The stiffener is spaced apart from the interposer. The stiffener includes a plurality of corner parts and a plurality of leg parts. Each of the plurality of leg parts connects corresponding two leg parts of the plurality of leg parts with each other and includes at least one bent part having an upwardly or downwardly convex shape. The plurality of leg parts are spaced apart from the package substrate.

According to an aspect of the present disclosure, a semiconductor package includes a package substrate, an interposer that is disposed on the package substrate, a semiconductor stack structure that is disposed on the interposer and in which a plurality of memory chips is vertically stacked on each other, a semiconductor chip that is disposed in a space between the interposer and the semiconductor stack structure, and a stiffener that is disposed on the package substrate and that is spaced apart from the interposer. The stiffener surround the interposer. The stiffener includes a plurality of corner parts and a plurality of leg parts. Each of the plurality of leg parts connects corresponding two leg parts of the plurality of leg parts with each other and includes at least one bent part having an upwardly or downwardly convex shape.

A semiconductor package according to an embodiment of the present disclosure includes a stiffener including leg parts that are spaced apart from a substrate and corner parts that are bonded to the substrate. Therefore, it is possible to improve the effect of reducing warpage of semiconductor packages of various sizes, thereby providing semiconductor packages with improved performance.

### BRIEF DESCRIPTION OF THE DRAWINGS

FIG. 1 is a perspective view illustrating a semiconductor package according to an embodiment of the present disclosure.

FIG. 2 is a plan view of the semiconductor package according to an embodiment of the present disclosure.

FIG. 3A to FIG. 3C are cross-sectional views taken along line AA′ of FIG. 1.

FIG. 4A and FIG. 4B show bent parts of leg parts according to an embodiment of the present disclosure.

FIG. 5A to FIG. 5F show a method of manufacturing the semiconductor package according to an embodiment of the present disclosure.

FIG. 6A to FIG. 6D shows a method of manufacturing the semiconductor package according to an embodiment of the present disclosure.

FIG. 7 shows a semiconductor package according to an embodiment of the present disclosure.

FIG. 8 shows a semiconductor package according to an embodiment of the present disclosure.

### DETAILED DESCRIPTION OF THE EMBODIMENTS

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Hereinafter, embodiments of the present disclosure will be described in detail such that they can be easily carried out by those skilled in the art. However, the present disclosure may be modified in various different ways, and are not limited to the embodiments to be described herein.

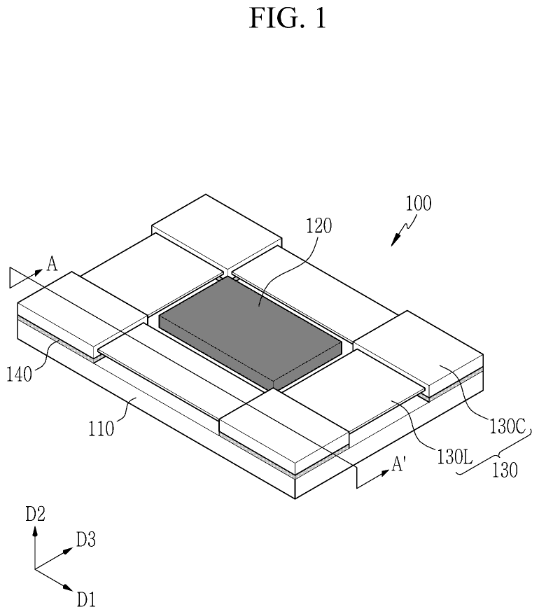

FIG. 1 is a perspective view of a semiconductor package 100 according to an embodiment of the present disclosure.

Referring to FIG. 1, the semiconductor package 100 includes a package substrate 110, a semiconductor chip 120, and a stiffener 130. For example, the semiconductor package 100 includes the package substrate 110, the semiconductor chip 120 that is bonded to the package substrate 110, and the stiffener 130 that is adjacent to the semiconductor chip 120 and is bonded to the package substrate 110.

The package substrate 110 is a member which can be coupled to external connection terminals through solder bumps and where semiconductor chips 120 can be mounted. Examples of the package substrate 110 may include various forms of substrates for semiconductor packaging, such as printed circuit board (PCB) substrates, ceramic substrates, glass substrates, and tape wiring substrates.

The semiconductor chip 120 may include a semiconductor chip substrate and an element layer. The semiconductor chip substrate may be a substrate containing a semiconductor element. Examples of the semiconductor element may include elements such as silicon (Si) and germanium (Ge). In an embodiment, the semiconductor chip substrate may contain or may be formed of, for example, a compound semiconductor such as silicon carbide (SiC), gallium arsenide (GaAs), indium arsenide (InAs), and indium phosphide (InP), but is not limited thereto.

In an embodiment, the semiconductor chip substrate may have a silicon-on-insulator (SOI) structure. For example, the semiconductor chip substrate may include a buried oxide layer (BOX layer). The substrate may include conductive regions such as wells doped with impurities and structures doped with impurities. The semiconductor chip substrate may include various element isolation structures such as shallow trench isolation (STI) structures.

In an embodiment, the element layer may include various types of elements according to the type of chips. For example, the element layer may include passive elements or various active elements such as planar field effect transistors (FETs) and FinFETs, memories such as flash memories, dynamic random access memories (DRAMs), static random access memories (SRAMs), electrically erasable programmable read-only memories (EEPROMs), phase-change random access memories (PRAMs), magnetoresistive random access memories (MRAMs), ferroelectric random access memories (FeRAMs), and resistive random access memories (RRAMs), logic gates such as AND, OR, and NOT gates, a system LSI (large-scale integration), CMOS imaging sensors (CISs), or a micro-electro-mechanical system (MEMS). In an embodiment, the element layer may include volatile memory semiconductor chips such as DRAMs and SRAMs, or non-volatile memory elements such as PRAMs, MRAMs, FeRAMs, and RRAMs.

In an embodiment, when the semiconductor chip 120 has a structure in which a plurality of semiconductor chips are stacked, each of the plurality of semiconductor chips may include a substrate portion and through-silicon vias (TSVs). The substrate portion may include a substrate and an element layer, and the substrate may contain or may be formed of a semiconductor element, similarly to the semiconductor chip substrate as described above in detail.

The TSVs are structures for electrically coupling structures disposed on the upper part and lower part of the substrate portion, and may extend from the upper surface of the substrate portion to the lower surface of the substrate portion and pass through the semiconductor chip substrate. The TSVs may have, for example, a columnar shape. The TSVs may be composed of, for example, various conductive materials such as copper (Cu), tungsten (W), nickel (Ni), ruthenium (Ru), and cobalt (Co), but are not limited thereto.

The stiffener 130 may be bonded to the upper surface of the package substrate 110. In an embodiment, the stiffener 130 may be bonded to the package substrate 110, and may be disposed near the semiconductor chip 120 to reduce warpage of the semiconductor package 100.

In an embodiment, the stiffener 130 may surround the semiconductor chip 120. In an embodiment, the stiffener 130 may have, for example, a rectangular ring shape, and may surround the semiconductor chip 120. The stiffener 130, when viewed in a plan view, may be spaced apart from the semiconductor chip 120 by a predetermined distance. For example, when viewed in a plan view, the semiconductor chip 120 may be disposed in an inner region defined by the rectangular ring shape of the stiffener 130 and an outer boundary of the semiconductor chip 120 and an inner surface of the rectangular ring shape may be spaced apart from each other at a predetermined distance. When the semiconductor package becomes warped during the semiconductor packaging process, the stiffener 130 may apply stress to the semiconductor package in the opposite direction to the direction of warping, thereby reducing the warpage of the semiconductor package 100.

In an embodiment, the stiffener 130 may contain or may be formed of at least one of aluminum (Al), stainless steel, and an engineering plastic material. The stiffener 130 is a material for reducing warpage of the semiconductor package, and may be formed of various materials capable of expansion and contraction besides the above-mentioned materials.

In an embodiment, the stiffener 130 may include corner parts 130C and leg parts 130L. The corner parts 130C refer to members which are disposed on the corner areas (i.e., corner regions) of the package substrate 110, and the leg parts 130L refer to members which are disposed between the corner parts 130C and connect the corner parts 130C.

The corner parts 130C may be members having a rectangular shape when viewed in a plan view. However, the present disclosure is not limited thereto. In an embodiment, the corner parts 130C may have various shapes for bonding the stiffener 130 to the package substrate 110, for example, shapes with curved corners or polygonal shapes.

In an embodiment, the leg parts 130L may be disposed apart from the package substrate 110. Before the leg parts 130L are mounted on the package substrate 110, compressive or tensile stress may be biaxially applied to the leg parts, and the leg parts with the residual stress may be bonded to the package substrate 110, such that the stress is transferred in the opposite direction to the direction of warpage of the semiconductor package 100. In this way, it is possible to control the semiconductor package 100 which warps during the semiconductor packaging process such that the semiconductor package flattens. For example, in the semiconductor packaging process, the leg parts 130L may be first subjected to compressive or tensile stress in two directions such that the leg parts 130L may have a residual stress before being bonded to the package substrate 110. The residual stress of the leg parts 130L may serve to control the warpage of the semiconductor package 100, ensuring that warpage of the semiconductor package 100 caused during the packing process is flattened.

In this case, the compressive or tensile stress biaxially applied to the leg parts 130L causes compressive or tensile stress to be applied to the corner parts 130C of the stiffener 130 on a plane relative to a first direction D1 and a third direction D3 such that the corner parts come into contact with the substrate 110. The leg parts 130L of the stiffener 130 which has secured the residual stress due to the compressive or tensile stress may be disposed in such a form that some regions are bent in a predetermined direction. In an embodiment, the compressive or tensile stress biaxially applied to the leg parts 130L causes a tensile or compressive stress to be applied to the corner parts 130C of the stiffener 130 such that the corner parts 130C contact the package substrate 110 on a plane defined by a first direction D1 and a third direction D3. The leg parts 130L of the stiffener 130 may have the residual stress due to the compressive or tensile stress, and the residual stress may cause some regions of the leg parts 130L to be bent in a predetermined direction so that the warpage of the semiconductor package 100 is flattened.

In an embodiment, the arrangement of the leg parts 130L apart from the substrate 110 may be a shape feature which is expressed by the residual stress, and may be a shape easy to control the stress in the opposite direction to the direction of the warpage of the semiconductor package 100.

The leg parts 130L having some regions bent in a predetermined direction may mean that the stiffener 130 subjected to biaxial compressive or tensile stress is implemented in the semiconductor package 100.

In an embodiment, the thickness of the corner parts 130C may be larger than the thickness of the leg parts 130L. The corner part 130C may be formed thicker than the leg parts 130L. This case is advantageous to apply deformation to control the residual stress before bonding the stiffener 130 to the package substrate 110, and it is possible to increase the flexural rigidity of the corner parts 130C where warpage significantly occurs.

In an embodiment, adhesive layers 140 may be disposed between the corner parts 130C and the package substrate 110. The adhesive layers 140 may be members for bonding the corner parts 130C and the package substrate 110. The adhesive layers 140 may be disposed on at least some areas of the corner parts 130C and may fix the stiffener 130 to the package substrate 110.

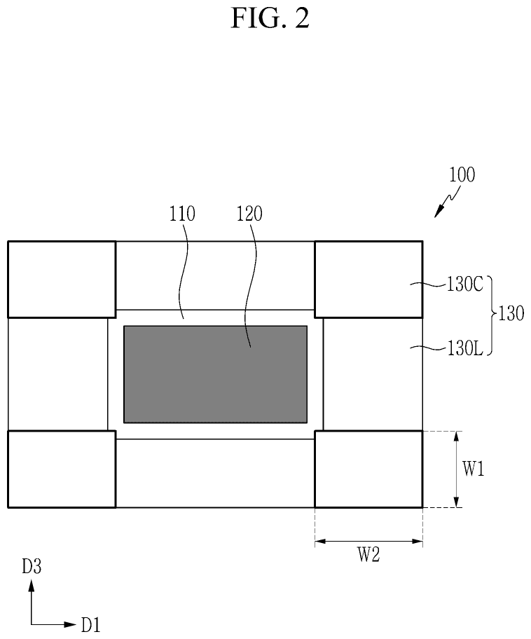

FIG. 2 is a plan view of the semiconductor package 100 according to an embodiment of the present disclosure.

Referring to FIG. 2, each of the corner parts 130C may be in the form of a rectangle with a first width W1 and a second width W2. The first width W1 refers to a length in the third direction D3 which is a direction perpendicular to the first direction D1 on a plane. The second width W2 may refer to the length of a corner part 130C in the first direction D1

In a plan view of a corner part 130C, the ratio of the second width W2 to the first width W1 may have a value selected from a range of 0.04 to 1. When the ratio satisfies the above-mentioned range, bonding to the package substrate 110 is easy, and stress which is applied to the semiconductor package 100 through the leg parts 130L can be uniformly applied. For example, in the range of the width ratio, bonding of the stiffener 130 to the package substrate 110 may be secured, and the residual stress of the leg parts 130L can be uniformly applied to the package substrate 110 to make the warpage of the semiconductor package 100 flattened.

In an embodiment, the first width W1 may have a value selected from a range of 1 mm to 35 mm. In an embodiment, the first width W1 may have a value selected from a range of 1 mm to 30 mm, more specifically, a range of 1 mm to 25 mm. The second width W2 may have a value selected from a range from 1 mm to 35 mm. In an embodiment, the second width W2 may have a value selected from a range of 1 mm to 25 mm, more specifically, a range of 1 mm to 10 mm.

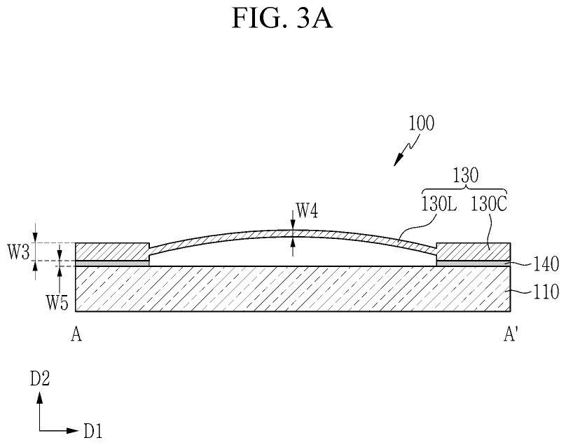

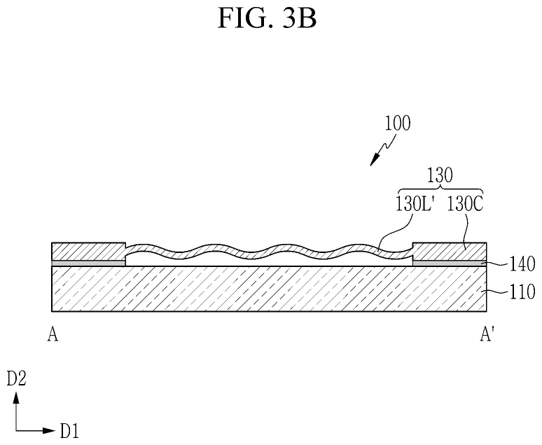

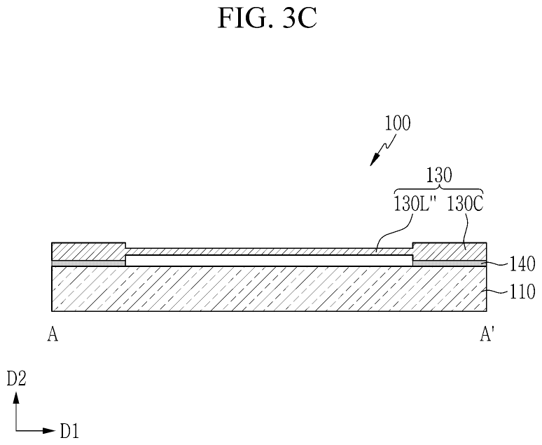

FIG. 3A to FIG. 3C are cross-sectional views taken along line AA′ of FIG. 1.

FIG. 3A shows that a bent shape of the leg parts 130L has a convex shape in the second direction D2. When a tensile stress is biaxially applied to the stiffener 130 including the leg parts 130L, and then the stiffener is bonded to the upper surface of the package substrate 110 in the semiconductor package 100 which has warped to be convex downward, i.e., in the opposite direction to the second direction D2, the leg parts 130L apply a residual tensile stress in the opposite direction to the direction of warpage of the semiconductor package 100, thereby flattening the warped semiconductor package 100 and maintaining the semiconductor package flat. Thereafter, the leg parts 130L can maintain the bent state in which the leg parts are bent to be convex in the second direction.

In an embodiment, the thickness of the corner parts 130C may be larger than the thickness of the leg parts 130L. The corner parts 130C may serve to bond and fix the stiffener 130 to the package substrate 110, and a residual stress of the leg parts 130L may contract or expand the leg parts 130L. For this reason, the corner parts 130C and the leg parts 130L are different from each other in thickness.

The ratio of the thickness W4 of the leg parts 130L to the thickness W3 of the corner parts 130C may have a value selected from a range of 0.05 to 0.95. In an embodiment, the thickness of the corner parts 130C may have a value of a range of 0.01 mm to 20 mm. In an embodiment, the thickness of the corner parts 130C may have a value selected from a range of 0.01 mm to 15 mm, and more specifically, the thickness of the corner parts 130C may have a value selected from a range of 0.01 mm to 10 mm.

When the ratio of the thickness W4 of the leg parts 130L to the thickness W3 of the corner parts 130C has a value selected from the above-mentioned range, it is possible to additionally apply stress in the opposite direction to the direction of stress causing warpage of the semiconductor package 100, using the deformed shape of the leg parts 130L caused by contraction of the original shape thereof due to the residual stress, thereby maximizing the effect of reducing warpage. When the ratio is out of the above-mentioned range, there is a problem that the effect of reducing warpage is insufficient.

In an embodiment, the ratio of the thickness of the adhesive layers 140 to the thickness of the corner parts 130C may have a value selected from a range of 0.0005 to 50. In an embodiment, the ratio of the thickness of the adhesive layers to the thickness of the corner parts may have a value selected from a range of 0.025 to 1. In an embodiment the thickness of the adhesive layers 140 may be in a range from 10 μm to 500 μm. In an embodiment, the thickness of the adhesive layers 140 may be in a range from 50 μm to 100 μm. When the thickness of the adhesive layers 140 satisfies the above-mentioned range, the adhesive layers can be easily bonded with the corner part 130C of the stiffener 130, and when the thickness of the adhesive layers is out of the above-mentioned range, the warpage reducing effect of the stiffener 130 may be insufficient.

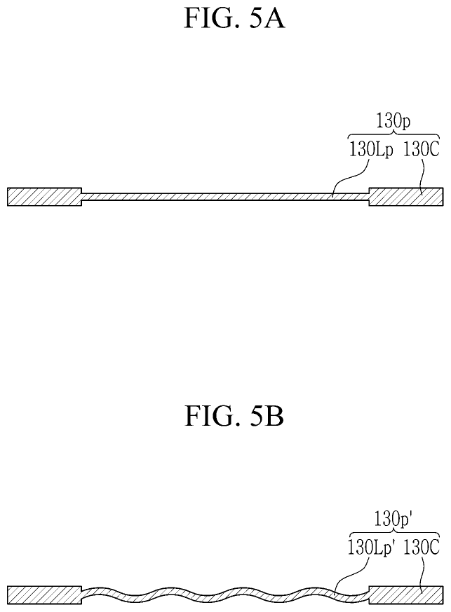

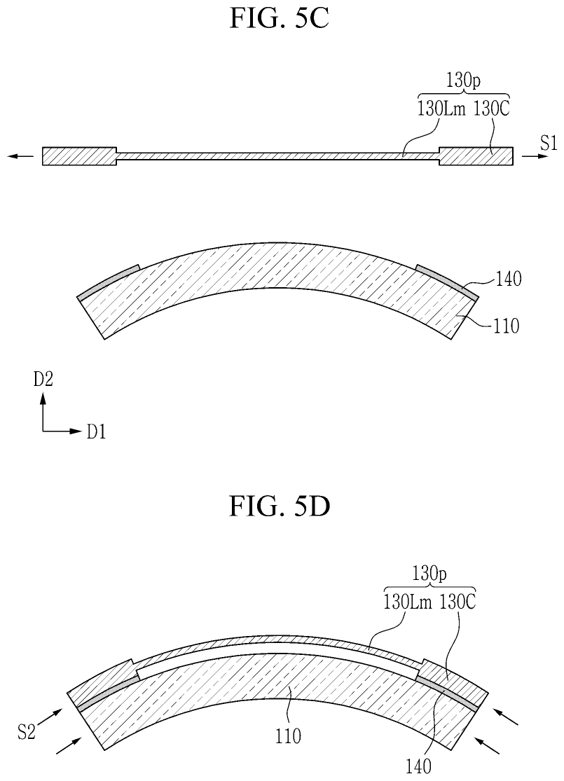

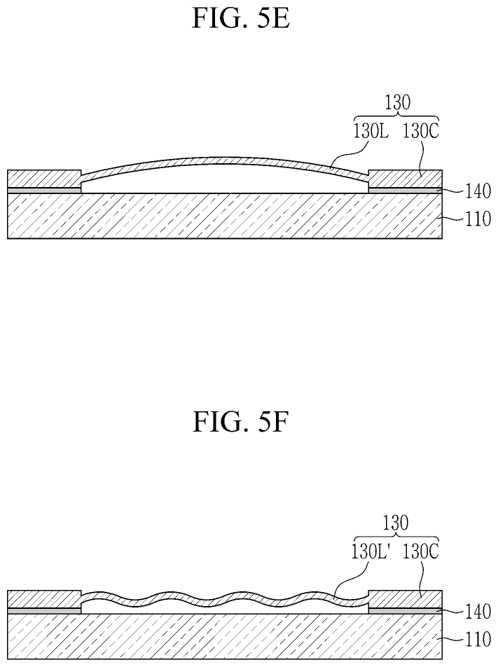

FIG. 3B shows that leg parts 130L′ each have one or more bent parts having a shape in which the leg parts 130L′ are bent to be convex in the second direction D2 and have a plurality of bent parts. Some bents may be convex in the second direction D2 and others may be convex in the opposite direction to the second direction D2 (a direction −D2). In an embodiment, the leg parts 130L′ have an upwardly bent shape and a downwardly bent shape which are alternately arranged to form a snake-moving shape. This will be described below in detail with reference to FIG. 5A to FIG. 5F.

FIG. 3C shows that leg parts 130L″ are disposed in the first direction D1 in parallel with the package substrate 110 with no parts convexly bent.

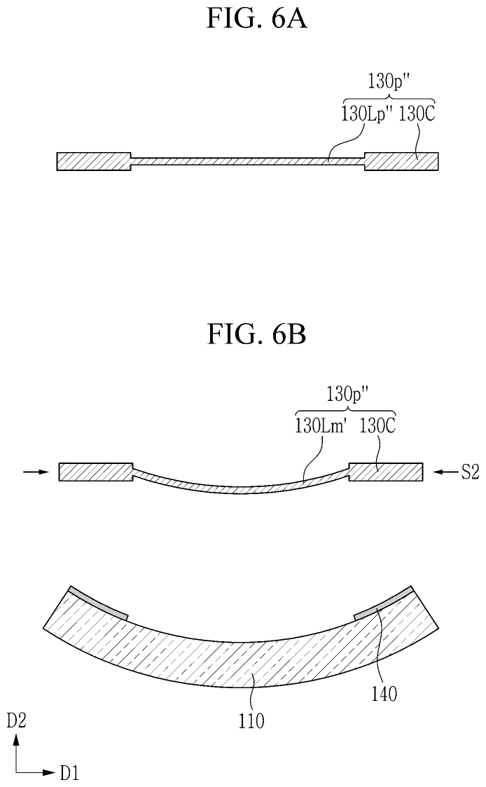

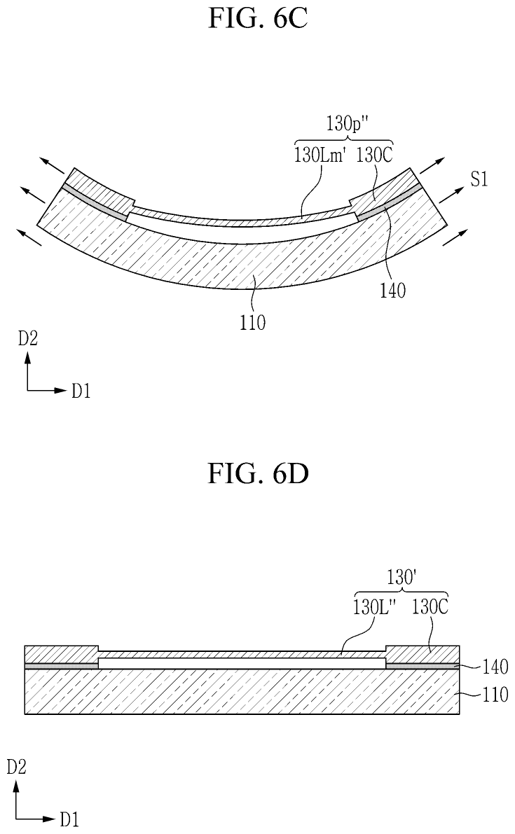

Referring to FIG. 3C, the leg parts 130L″ may be disposed apart from the package substrate 110 without being bent. During the semiconductor packaging process, the semiconductor package 100 may convexly warp in the opposite direction to the second direction D2 (the direction −D2). casein an embodiment, a compressive stress is applied to the stiffener 130 such that the stiffener has a tensile residual stress, and then the stiffener 130 is bonded to the package substrate 110. The tensile stress of the stiffener 130 may cause the warped semiconductor package 100 to have a flat shape. This will be described below in detail with reference to FIG. 6A to FIG. 6D.

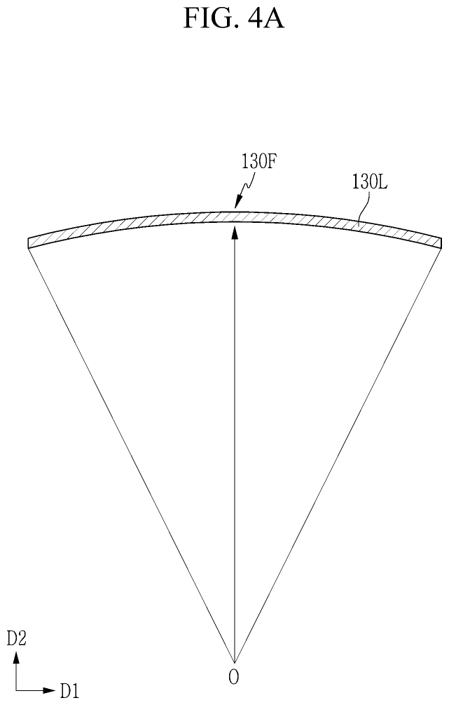

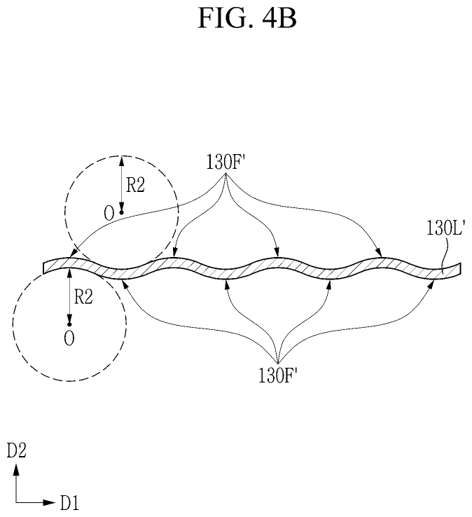

FIG. 4A and FIG. 4B show bent parts of leg parts 130L and 130L′ according to an embodiment of the present disclosure.

FIG. 4A shows a bent part 130F of the leg part 130L of FIG. 3A, and FIG. 4B shows a bent part 130F′ of the leg part 130L′ of FIG. 3B. In an embodiment, the leg parts 130L and 130L′ may have a bending shape or a serpentine shape (i.e., a moving snake shape) in at least some partial areas. The bending shape refers to a shape that is convex in the second direction D2 or in the opposite direction to the second direction D2 (the direction −D2), and the serpentine shape refers to a snaky shape and means that the shape includes a plurality of bent parts.

In an embodiment, each leg part 130L′ may have two to twenty bent parts 130F′. In an embodiment, each leg part 130L′ having the above-mentioned serpentine shape may have two to twenty bent parts 130F′.

In an embodiment, the radiuses R1, R2, and R2′ of the bent parts 130F and 130F′ may have a value selected from a range of 0.01 mm to 25000 mm. The radiuses R1, R2, and R2′ of the bent parts 130F and 130F′ refer to radiuses when circles are drawn based on the bent parts 130F and 130F′, and at least one of bent parts 130F and 130F′ having the radiuses R1, R2, and R2′ of the bent parts 130F and 130F′ is included. Therefore, it can be seen that a residual stress caused by deformation applied before bonding of the stiffener 130 to the substrate was easily controlled.

FIG. 5A to FIG. 5F show a method of manufacturing the semiconductor package 100 according to an embodiment of the present disclosure.

Referring to FIG. 5A and FIG. 5B, the method may include a step of preparing an unstressed pre-stiffener 130p. FIG. 5A shows a step of preparing an unstressed pre-stiffener 130p including pre-leg parts 130Lp without any bent parts, and FIG. 5B shows a step of preparing an unstressed pre-stiffener 130p′ including pre-leg parts 130Lp′, each of which includes at least one bent part. The pre-stiffener 130p may be prepared to be bondable to the package substrate 110 of the warped semiconductor package 100 which has been subject to a high-temperature semiconductor packaging process of stacking memory chips or semiconductor chips.

FIG. 5C shows that a biaxial stress is applied to the pre-stiffener 130p to bond the pre-stiffener 130p to the semiconductor package 100. In the high-temperature semiconductor packaging process, the semiconductor package 100 has been convexly warped in the second direction D2. In an embodiment, a tensile stress S1 is biaxially applied to the pre-stiffener 130p such that the pre-stiffener has a residual stress of compressive stress. The pre-stiffener 130p may apply a compressive residual stress to the semiconductor package 100 which is convexly warped in the second direction D2. The residual compressive stress is appliedin the opposite direction of the second direction D2. As compared to the pre-stiffener 130p of FIG. 5A, it can be seen that the pre-stiffener 130p of FIG. 5C subjected to tensile stress in the above-mentioned way has expanded leg parts 130Lm which are the expanded pre-leg parts 130Lp.

Referring to FIG. 5D, the pre-stiffener 130p subjected to the tensile stress S1 is bonded to the package substrate 110 of the warped semiconductor package 100. The residual stress of the expanded leg parts 130Lm may control the warpage of the semiconductor package 100. In an embodiment, the compressive residual stress S2 may act in the opposite direction to the direction of tensile stress S1, and due to the restorability of the expanded leg parts 130Lm, the compressive residual stress S2 may be applied to the warped semiconductor package 100 in the opposite direction to the direction of warpage to flatten the warped semiconductor package 100.

Referring to FIG. 5E and FIG. 5F, it can be seen that warpage of the semiconductor package 100 is prevented by the stiffener 130 subjected to tensile stress S1. In an embodiment, it can be seen that the stiffener 130 subjected to tensile stress S1 can be used to prevent warpage of the semiconductor package 100 from being caused by a thermal history in the process of manufacturing the semiconductor package 100. From the final product in which the stiffener 130 subjected to tensile stress S1 has been bonded to the semiconductor package 100, it can be seen that each of the leg parts 130L has at least one bent part, and these bent parts may be shapes caused by residual stress. For example, when the warped semiconductor package 100 is flattened using the residual stress of the leg parts 130L, the leg parts 130L may contract, which causes the leg parts 130L to have at least one bent as shown in FIGS. 5E and 5F.

FIG. 6A to FIG. 6D show a method of manufacturing the semiconductor package 100 according to an embodiment of the present disclosure.

Referring to FIG. 6A, the method may include a step of preparing an unstressed pre-stiffener 130p″. The pre-stiffener 130p″ may be prepared to be bondable to the package substrate 110 of the warped semiconductor package 100 which has been subject to a high-temperature semiconductor packaging process of stacking memory chips or semiconductor chips.

FIG. 6B shows that a biaxial stress is applied to a pre-stiffener 130p′ in order to bond the pre-stiffener 130p′ to the semiconductor package 100. In the high-temperature semiconductor packaging process, the semiconductor package 100 has been convexly warped in the opposite direction to the second direction D2. In an embodiment, a compressive stress S2 is biaxially applied to the pre-stiffener 130p′ such that the pre-stiffener has a residual stress of a tensile stress. The pre-stiffener 130p′ may apply a tensile residual stress to the semiconductor package 100 which is convexly warped in the opposite direction to the second direction D2. The tensile residual stress is applied in the second direction D2. It can be seen that when the compressive stress is applied to the pre-stiffener 130p′, contracted leg parts 130Lm′ are formed.

Referring to FIG. 6C, the pre-stiffener 130p′ subjected to the compressive stress S2 is bonded to the package substrate 110 of the warped semiconductor package 100. The residual stress of the contracted leg parts 130Lm′ may control the warpage of the semiconductor package 100. In an embodiment, the compressive stress S2 may act in the opposite direction to the direction of the tensile stress S1, and due to the restorability of the contracted leg parts 130Lm′, the tensile residual stress may be applied to the warped semiconductor package 100 in the opposite direction to the direction of warpage to flatten the warped semiconductor package 100.

Referring to FIG. 6D, it can be seen that warpage of the semiconductor package 100 is prevented by the stiffener 130′ subjected to the compressive stress S2. In an embodiment, it can be seen that the stiffener 130′ subjected to the compressive stress S2 can be used to prevent warpage of the semiconductor package 100 from being caused by a thermal history in the process of manufacturing the semiconductor package 100. From the final product in which the stiffener 130′ subjected to the compressive stress S2 has been bonded to the semiconductor package 100, it can be seen that the stiffener is spaced apart from the package substrate 110 and has a shape with no bent parts. For example, when the warped semiconductor package 100 is flattened using the residual stress of the leg parts 130Lm′, the leg parts 130m′ may extend, which causes the leg parts 130Lm′ to be flattened with no bent parts as shown in FIG. 6E.

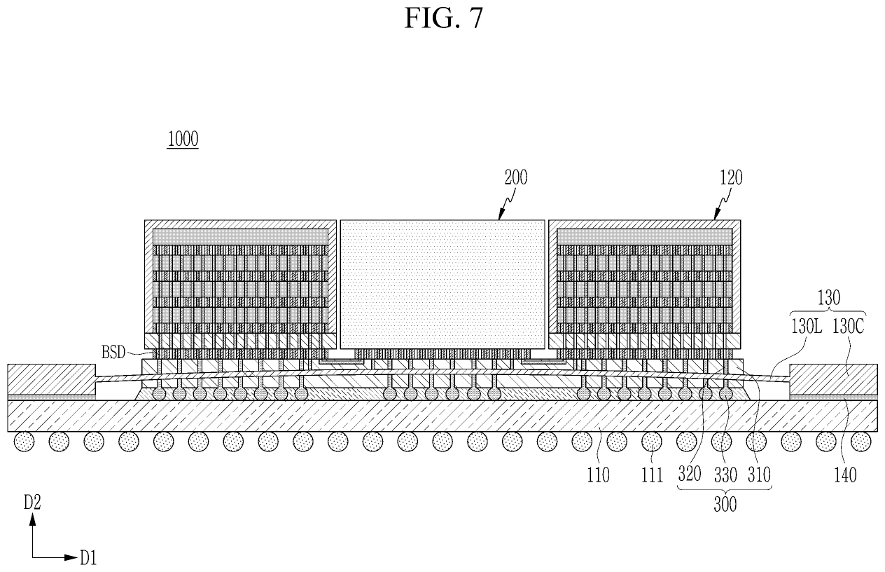

FIG. 7 shows a semiconductor package 1000 according to an embodiment of the present disclosure, which may include a plurality of semiconductor chips 120 and 200, a stiffener 130, and an interposer 300. For example, the semiconductor package 1000 may be a 2.5D semiconductor package of the plurality of semiconductor chips 120 and 200 without vertically stacking the semiconductor chips 120 and 200.

On the package substrate 110, external connection terminals 210 such as solder bumps may be disposed. The semiconductor package 1000 may be mounted on another external board and may be electrically coupled to other devices through the external connection terminals 210.

In an embodiment, each of the semiconductor chips 120 of the plurality of semiconductor chips 120 and 200 may have a structure in which a plurality of memory chips is vertically stacked. The plurality of semiconductor chips 120 may include bump structures BSD which electrically couple the plurality of the semiconductor chips 120 to the interposer 300. The bump structures BSD couple the plurality of semiconductor chips 120 which are disposed in the semiconductor package 1000, in one direction, thereby electrically coupling the semiconductor chips to the interposer 300.

Of the semiconductor chips 120 and 200, the other semiconductor chip 200 may be a processor chip. The semiconductor chip 200 may be disposed side by side with the semiconductor chip 120 and may be mounted on the interposer 300. The semiconductor chip 200 may be a logic chip, for example, a GPU/CPU/SOC chip. According to the types of elements included in the semiconductor chip 200, the semiconductor package 1000 may be classified into a semiconductor package 1000 for servers or a semiconductor package for mobile devices.

The interposer 300 may be disposed on the package substrate 110 and may be used to convert or transmit electrical input signals between the package substrate 110 and each of the plurality of semiconductor chips 120 and 200. The interposer 300 may include an interposer substrate 310, interposer TSVs 320, interposer pads (not shown in the drawing), an interposer wiring layer (not shown in the drawing), and interposer bumps 330.

The interposer substrate 310 may be formed from any one of silicon, organic material, plastic, and glass substrates. For example, when the interposer substrate 310 of the interposer 300 is a silicon substrate, the interposer 300 may be used as a panel interposer.

The interposer TSVs 320 may extend from the upper surface of the interposer substrate 310 to the lower surface of the interposer substrate and pass through the interposer substrate 310. The interposer TSVs 320 may extend into the interposer wiring layer. When the interposer substrate 310 is silicon, the through-silicon vias 320 may be referred to as TSVs. In an embodiment, inside the interposer 300, only the interposer wiring layer may be included, and any interposer TSVs 320 may not be included.

The interposer pads may be disposed on the upper surface of the interposer substrate 310, and may be electrically coupled to the interposer TSVs 320. On the interposer pads, the semiconductor chips 120 and 200 may be disposed to be electrically coupled to the package substrate 110. In an embodiment, the semiconductor chip 200 may serve as a processor chip.

The interposer bumps 330 may be disposed below the interposer 300, and may be electrically coupled to wiring lines of the interposer wiring layer. Using the interposer bumps 330, the interposer 300 may be mounted on the package substrate 110 such as a printed circuit board (PCB). The interposer bumps 330 may be coupled to the interposer pads through the wiring lines of the interposer wiring layer and the interposer TSVs 320.

In an embodiment, the stiffener 130 may be disposed on the package substrate 110. On the package substrate 110, the stiffener 130 may be mounted with the semiconductor chips 120 and 200, and the interposer 300. The stiffener 130 has been described above in detail, and the repeated descriptions thereof will be omitted.

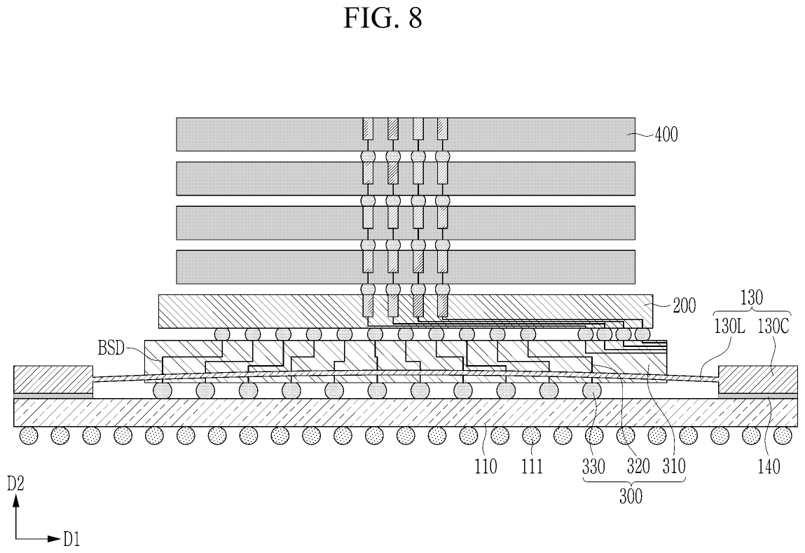

FIG. 8 shows a semiconductor package 1000 according to an embodiment of the present disclosure.

Referring to FIG. 8, the semiconductor package 1000 of the present disclosure may include a package substrate 110, an interposer 300 that is disposed on the package substrate 110, a plurality of semiconductor chips 200 and 400 that include dies and are disposed on the interposer 300, and a stiffener 130 that is disposed on the package substrate 110. The stiffener 130 may be spaced apart from the interposer 300 and surround the interposer 300. The semiconductor package shown in FIG. 8 may be, for example, a three-dimensional (3D) semiconductor package in which the plurality of semiconductor chips 120 and 400 are vertically stacked on each other.

In an embodiment, the stiffener 130 may be disposed on the package substrate 110, and may be spaced apart from the side surfaces of a structure formed by sequentially stacking the interposer 300, the semiconductor chip 400 which is a logic chip among the semiconductor chips 120 and 400, and the plurality of semiconductor chips 120 including memory chips. The stiffener 130 may minimize interference with the interposer 300 and the plurality of semiconductor chips 120 and 400. The package substrate 110, the plurality of semiconductor chips 120 and 400, the interposer 300, and the stiffener 130 have been described above in detail, and thus repeated descriptions thereof are omitted.

In an embodiment, the adhesive layers 140 may be disposed between the corner parts 130C of the stiffener 130 and the package substrate 110. The adhesive layers 140 may be members for fixing the stiffener 130 to the package substrate 110. The adhesive layers 140 have been described above in detail, and the above description may be referred to.

As shown in FIG. 7 and FIG. 8, the stiffener 130 may be applied not only to flip chip on packaging but also to 2.5D semiconductor packages, 2.1D semiconductor packages, or 3D semiconductor packages having structures in which a plurality of semiconductor chips is disposed. The 2.1D semiconductor packages may have a high-density wiring layer on the chip side of a substrate acting as an interposer without using silicon/glass interposers of 2.5D semiconductor packages,

The present disclosure is not limited to the above implementation examples and/or embodiments, and may be manufactured in various other forms, and those skilled in the art will understand that the present disclosure may be carried out in other specific forms without altering the technical spirit and essential features of the present disclosure. It should therefore be appreciated that the implementation examples and/or embodiments described above are examples in all respects and are not intended to be limiting.

### Description of symbols

100, 1000: Semiconductor package 110: Package substrate
120, 400: Semiconductor chip 130, 130′: Stiffener
130C: Corner part 130L, 130L′: Leg part
130F, 130F′: Bent part 140: Adhesive layer
300: Interposer

What is claimed is:

1. A semiconductor package comprising:
a package substrate;
a semiconductor chip that is bonded to the package substrate; and
a stiffener that is adjacent to the semiconductor chip and is bonded to the package substrate,
wherein the stiffener includes a plurality of corner parts that are bonded to a plurality of corner regions of the package substrate, and a plurality of leg parts that are spaced apart from the package substrate, and
wherein each of the plurality of leg parts connects corresponding two leg parts of the plurality of leg parts with each other.

2. The semiconductor package of claim 1,
wherein the plurality of leg parts have residual stresses.

3. The semiconductor package of claim 1,
wherein the stiffener surrounds the semiconductor chip.

4. The semiconductor package of claim 1,
wherein each of the plurality of corner parts has a first thickness, and
wherein each of the corresponding two leg parts has a second thickness smaller than the first thickness.

5. The semiconductor package of claim 4,
wherein a ratio of the first thickness to the second thickness has a value selected from a range of 0.05 to 0.95.

6. The semiconductor package of claim 4,
wherein the first thickness of each of the plurality of corner parts has a value selected from a range of 0.01 mm to 10 mm.

7. The semiconductor package of claim 1,
wherein each of the plurality of leg parts has at least one bent part.

8. The semiconductor package of claim 7,
wherein the at least one bent part has a bending shape.

9. The semiconductor package of claim 1,
wherein each of the plurality of leg parts includes two to twenty bent parts which form a serpentine shape.

10. The semiconductor package of claim 7,
wherein a radius of each of the at least one bent has a value selected from a range of 0.01 mm to 25000 mm.

11. The semiconductor package of claim 1, further comprising:
a plurality of adhesive layers between the plurality of corner parts and the plurality of corner regions of the package substrate, respectively.

12. The semiconductor package of claim 11,
wherein a ratio of a thickness of each of the plurality of adhesive layers to a thickness of a corresponding one of the plurality of corner parts has a value selected from a range of 0.0005 to 50.

13. The semiconductor package of claim 12,
wherein the thickness of each of the plurality of adhesive layers has a value selected from a range of 10 μm to 500 μm.

14. The semiconductor package of claim 1,
wherein the stiffener contains at least one of aluminum (Al), stainless steel, and an engineering plastic material.

15. A semiconductor package comprising:
a package substrate;
an interposer that is mounted on the package substrate;
a semiconductor stack structure that is disposed on the interposer and in which a plurality of memory chips is vertically stacked on the interposer;
a semiconductor chip that is horizontally adjacent to the semiconductor stack structure and that is mounted on the interposer; and
a stiffener that is disposed on the package substrate, and that surrounds the interposer,
wherein the stiffener is spaced apart from the interposer,
wherein the stiffener includes a plurality of corner parts and a plurality of leg parts,
wherein each of the plurality of leg parts connects corresponding two leg parts of the plurality of leg parts and includes at least one bent part having an upwardly or downwardly convex shape, and
wherein the plurality of leg parts are spaced apart from the package substrate.

16. The semiconductor package of claim 15,
wherein each of the plurality of leg parts includes two to twenty bent parts which form a serpentine shape.

17. The semiconductor package of claim 16,
wherein a radius of each of the plurality of leg parts has a value selected from a range of 0.01 mm to 25000 mm.

18. The semiconductor package of claim 15,
wherein each of the plurality of corner parts has a first thickness, and
wherein each of the corresponding two leg parts has a second thickness smaller than the first thickness.

19. The semiconductor package of claim 18,
wherein a ratio of the first thickness to the second thickness has a value selected from a range of 0.05 to 0.95.

20. A semiconductor package comprising:
a package substrate;
an interposer that is disposed on the package substrate;
a semiconductor stack structure that is disposed on the interposer and in which a plurality of memory chips is vertically stacked on each other;
a semiconductor chip that is disposed in a space between the interposer and the semiconductor stack structure; and
a stiffener that is disposed on the package substrate and that is spaced apart from the interposer,
wherein the stiffener surround the interposer,
wherein the stiffener includes a plurality of corner parts and a plurality of leg parts, and
wherein each of the plurality of leg parts connects corresponding two leg parts of the plurality of leg parts with each other and includes at least one bent part having an upwardly or downwardly convex shape.
